(19) United States
(12) Patent Application Publication
(10) Pub. No.: US 2002/0009850 A1
(43) Pub. Date: Jan. 24, 2002

(54) MULTI-LAYER POLYSILICON PLUG AND METHOD FOR MAKING THE SAME

(76) Inventor: OSBERT CHENG, HSINCHU (TW)

Correspondence Address: OPPENHEIMER WOLFF & DONNELLY, P. O. BOX 10356, PALO ALTO, CA, 94303, US

(21) Appl. No.: 09/447,325

(22) Filed: Nov. 22, 1999

(51) Int. Cl. H01L 21/8242; H01L 21/4763

(52) U.S. Cl. 438/256; 438/647; 438/672

(57) ABSTRACT

A method for making a multi-layer polysilicon plug forms a plurality of undoped polysilicon thin layers alternating with a plurality of doped polysilicon thin layers on a substrate having a concavity until the polysilicon layers fill the concavity. Thus, a multi-layer polysilicon layer is formed. The multi-layer polysilicon layer is patterned and etched to form a multi-layer polysilicon plug in the concavity.

### BACKGROUND OF THE INVENTION

1.Field of Invention

The present invention relates to integrated circuit devices. More particularly, the present invention relates to a multi-layered polysilicon plug and method for making the same.

2. Description of Related Art

Doped polysilicon is commonly used as conducting material in integrated circuits. For example, doped polysilicon can be used for making word-line, bit-line or interconnection (such as bit-line contact or node contact). The conductivity of doped polysilicon depends on the concentration of dopants that are incorporated in the polysilicon.

Continuous scaling-down of DRAM cell magnifies the short-channel effect due to dopant out-diffusion from the poly-interconnection. The dopants introduced in the polysilicon would out-diffuse to the substrate during annealing process. As the integration of a semiconductor device increases, junction depth of the semiconductor device accordingly decreases. The out-diffusion of dopants from doped polysilicon may result in a deeper junction in semiconductor devices.

FIG. 1 is a schematic, cross-sectional view showing the conventional doped polysilicon plug. As shown in FIG. 1, the conventional doped-polysilicon plug 100 is formed on a source region 102. Rj is the junction depth of the source region 102. The conventional method for manufacturing the doped polysilicon plug 100 is stated as follow. At first, an in-situ doped polysilicon layer (not shown in FIG. 1) is blanket-deposited in a batch-type CVD chamber after the transistors 104, 106 and source region 102 are finished. Thereafter, the doped polysilicon layer is patterned and etched to form the doped polysilicon plug 100.

The dopants 110 in the doped polysilicon plug 100 diffuse out and enter into the substrate 112 during the annealing process, and increase the junction depth (Rj). Therefore, the doping concentration must be carefully controlled to avoid excessive out-diffusion of the dopants from the doped polysilicon plug.

As line width and junction depth of devices are continuously required to reduce, the dopant concentration of the doped polysilicon plug should be decreased for a shallow junction depth. However, the sheet resistance and the contact resistance rise when the doping concentration of a doped polysilicon plug decreases. Whether to maintain low resistance or to have a shallow junction depth is a dilemma in current technology development.

Therefore, a method for fabricating a doped plug with low out-diffusion is required.

### SUMMARY OF THE INVENTION

Accordingly, a multi-layer polysilicon plug is provided to inhibit dopant out-diffusion and maintain low resistance.

To achieve this and other advantages and in accordance with the purpose of the invention, this invention provides a method for making a multi-layer polysilicon plug, comprising the following steps. A plurality of thin undoped-polysilicon layers and a plurality of thin doped-polysilicon layers are alternately formed on a substrate having a concavity thereon, and fill the concavity, thus a multi-layered polysilicon layer is formed. The multi-layered polysilicon layer are patterned and etched to form a multi-layer polysilicon plug in the concavity.

In one aspect of the invention, the multi-layered polysilicon layer is in-situ doped in one chamber.

In another aspect of the invention, the doped polysilicon layers and the undoped polysilicon layers are formed in the same chamber by using High Temperature Film (HTF)-type CVD equipment.

In a further aspect of the invention, the doped polysilicon layers and the undoped polysilicon layers have substantially conformal profile.

In a further aspect of the invention, the doped polysilicon layers and the undoped polysilicon layers have substantially conformal profile.

As embodied and broadly described herein, this invention provides a multi-layer polysilicon structure to inhibit the dopant out-diffusion and maintain the low sheet resistance and contact resistance. The multi-layer structure comprises: a plurality of undoped polysilicon thin layers and a plurality of doped polysilicon thin layers. Each of the undoped polysilicon thin layers and each of the doped polysilicon thin layers are alternately stacked together.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-section view showing a conventional doped polysilicon plug; and

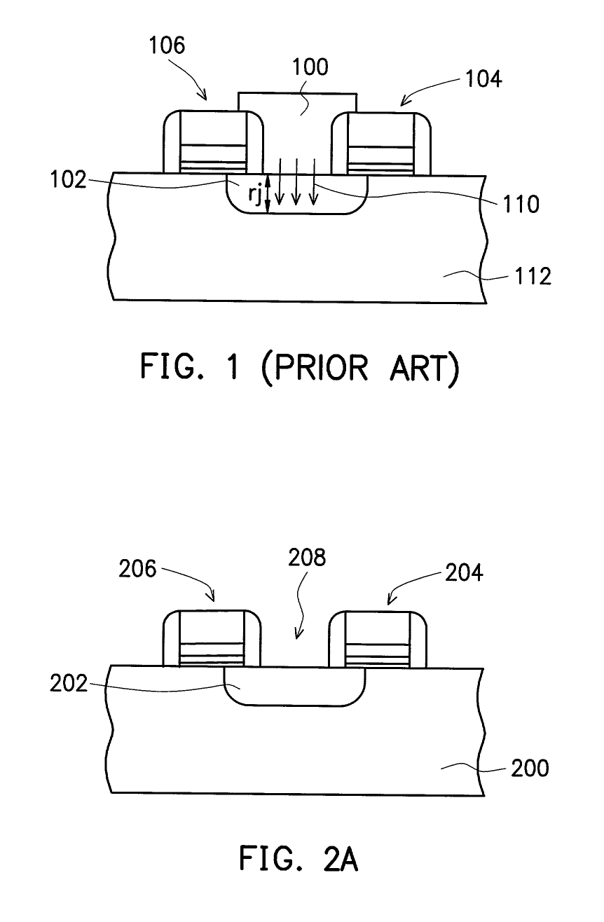

FIG. 2A to FIG. 2C are schematic, cross-section views showing the manufacturing method of a multi-layered polysilicon plug according to one preferred embodiment of this invention.

### DESCRIPTION OF THE PREFERRED EMBODIMENTS

A landing pad for a node contact of DRAM process is illustrated as an example in the following description.

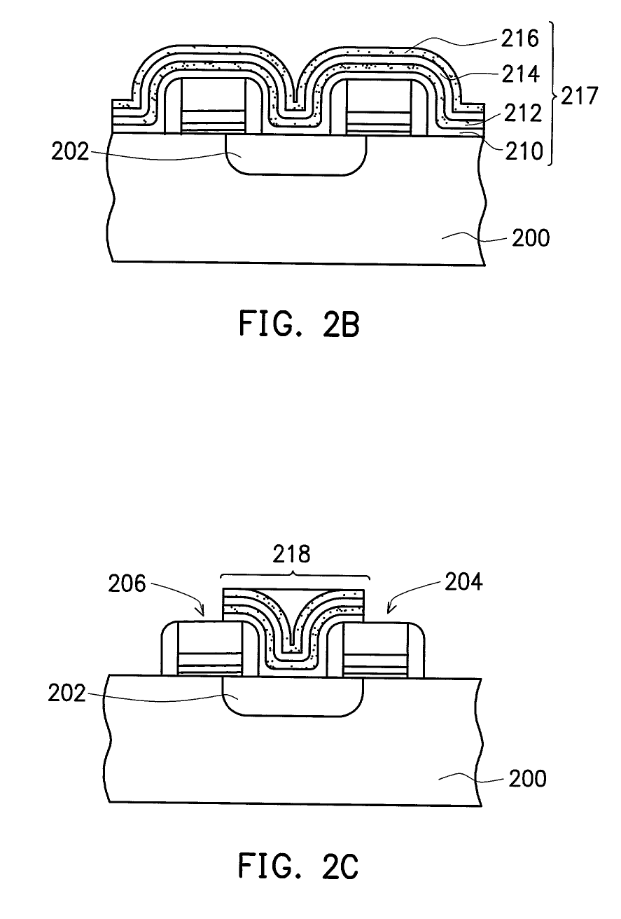

FIG. 2A to 2C are schematic, cross-section views showing the process for forming a multi-layer polysilicon plug according to one preferred embodiment of this invention.

Referring to FIG. 2A, a substrate 200 is provided. On the substrate 200, several devices, for example, transistors 204, 206 and source/drain regions 202 have been formed. A concavity 208 is located above the source/region 202 and between the two transistors. The concavity 208 is in the position where the plug will be formed. The concavity 208 can be a bit-line contact, a node contact and the like.

Next, referring to FIG. 2B, an undoped polysilicon thin layer 210 is formed on substrate 200, and covers the transistors 204, 206 and source/drain region 202. After that, a doped polysilicon thin layer 212 is formed on the undoped polysilicon thin layer 210. Then, undoped polysilicon thin layers and doped polysilicon layers are alternatingly formed on the doped to fill the concavity 208, resulting in a multi-layered polysilicon layer 217. Each of the undoped polysilicon layers and the doped polysilicon layers are conformal to the concavity 208.

Preferably, the doped polysilicon layers and undoped polysilicon layers are formed in a High Temperature Film (HTF)-type CVD chamber. For example, a wafer is placed in the chamber of HTP-type CVD equipment. Then, an in-situ CVD process is performed to deposit the doped and undoped polysilicon layers. The valve of the dopants is alternately opened and closed corresponding to forming the doped and undoped polysilicon layers. The time that the valve open or closed can be adjusted to set up the thickness of silicon layers.

Referring to FIG. 2C, the multi-layer polysilicon layer 217 is patterned and etched to form a multi-layer polysilicon plug 218 in the concavity 208. The method for patterning and etching the multi-layer polysilicon layer 217 can be any conventional adapted process.

In this embodiment, the reason for using the HTF-type CVD reactor to form the multi-layer polysilicon layer is that the HTF-type CVD reactor has a smaller chamber volume than that of the Batch-type CVD reactor. Therefore, the dopants in the chamber of the HTF-type CVD reactor have a consumption rate much higher than that in Batch-type CVD reactor.

Due to the multi-layer stacked structure, the out-diffusion phenomenon is inhibited by the undoped polysilicon layers.

In addition, the bottom layer of the multi-layer polysilicon plug is undoped. After a thermal annealing process, the undoped bottom polysilicon layer has a doping concentration gradient. That is, the doping concentration decreases monotonically from the upper surface of the undoped layer. Therefore, the junction depth can be adjusted by changing the thickness of the bottom polysilicon layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for making a multi-layer polysilicon plug, comprising the steps of:
alternatingly forming a plurality of undoped polysilicon thin layers and a plurality of doped polysilicon thin layers on a substrate having a concavity thereon, and thus forming a multi-layer polysilicon layer; and
patterning and etching the multi-layer polysilicon layer to form the multi-layer polysilicon plug in the concavity.

2. The method of claim 1, wherein the doping concentration of each doped polysilicon thin layer is substantially the same.

3. The method of claim 1, wherein the doped polysilicon thin layers are in-situ doped during the formation of the doped polysilicon thin layers.

4. The method of claim 1, wherein the undoped polysilicon thin layers and the doped polysilicon thin layers are formed in a same chamber.

5. The method of claim 4, wherein the undoped polysilicon thin layers and the doped polysilicon thin layers are formed in the chamber of a HTF-type CVD reactor.

6. The method of claim 1, wherein the concavity comprises a bit-line contact.

7. The method of claim 1, wherein the concavity comprises a node contact.

8. The method of claim 1, wherein the undoped polysilicon thin layers and the doped polysilicon thin layers are substantially conformal to a substrate topography.

9. A multi-layer polysilicon plug formed in a concavity on a substrate, the multi-layer polysilicon plug comprising:
a plurality of undoped polysilicon thin layers; and
a plurality of doped polysilicon thin layers, wherein the undoped polysilicon thin layers and the doped polysilicon thin layers are alternatingly stacked together.

10. The multi-layer polysilicon plug of claim 9, where in the undoped polysilicon thin layers and the doped polysilicon thin layers are substantially conformal.

11. The multi-layer polysilicon plug of claim 9, wherein the concavity comprises a bit-line contact.

12. The multi-layer polysilicon plug of claim 9, wherein the concavity comprises a node contact.

13. The multi-layer polysilicon plug of claim 9, wherein the doping concentration of each the doped polysilicon thin layer is substantially the same.

14. A method for inhibiting an out-diffusion of dopants from doped polysilicon, comprising the steps of:
alternatingly forming a plurality of undoped polysilicon thin layers and a plurality of doped polysilicon thin layers on a substrate having a concavity thereon, and thus forming a multi-layer polysilicon layer; and
patterning and etching the multi-layer polysilicon layer to form the multi-layer polysilicon plug in the concavity.

15. The method of claim 14, wherein the doped polysilicon thin layers are in-situ doped during the formation of the doped polysilicon thin layers.

16. The method of claim 14, wherein the undoped polysilicon thin layers and the doped polysilicon thin layers are formed in a same chamber.

17. The method of claim 16, wherein the undoped polysilicon thin layers and the doped polysilicon thin layers are formed in the chamber of a HTF-type CVD reactor.

18. The method of claim 14, wherein the concavity comprises a bit-line contact.

19. The method of claim 14, wherein the concavity comprises a node contact.

20. The method of claim 14, wherein the undoped polysilicon thin layers and the doped polysilicon thin layers are substantially conformal.
